(19) United States
(12) Patent Application Publication
(10) Pub. No.: US 2007/0200196 A1
(43) Pub. Date: Aug. 30, 2007

(54) Shallow trench isolation (STI) devices and processes

(75) Inventors: Anish Kumar, Portland, OR (US); Moshe Agam, Portland, OR (US); Gary Kwon, Portland, OR (US)

Correspondence Address: MACPHERSON KWOK CHEN & HEID LLP, 2033 GATEWAY PLACE, SUITE 400, SAN JOSE, CA, 95110, US

(73) Assignee: Lattice Semiconductor Corporation

(21) Appl. No.: 11/361,585

(22) Filed: Feb. 24, 2006

(51) Int. Cl. H01L 29/00; H01L 21/762

(52) U.S. Cl. 257/506; 438/435; 438/427; 257/510

(57) ABSTRACT

Improved shallow trench isolation (STI) techniques are provided for semiconductor devices. For example, in accordance with an embodiment of the present invention, an integrated circuit includes a substrate, a first trench in the substrate, and a second trench in the substrate. A first transistor region in the substrate is adjacent to and between the first and second trenches. A silicon dioxide liner substantially lines the first and second trenches. A silicon nitride liner is on the silicon dioxide liner in the first trench but not on the silicon dioxide liner in the second trench. A dielectric material fills the first and second trenches.

### TECHNICAL FIELD

The present invention relates generally to integrated circuits and, more particularly, to the isolation of integrated circuit components.

### BACKGROUND

Integrated circuits having transistors in close proximity to each other can often exhibit unintended current leakage between adjacent transistors. As a result, various isolation techniques have been developed to reduce such leakage currents.

Shallow trench isolation (STI) is one conventional approach frequently used to reduce leakage currents for integrated circuits having nominal feature sizes approximately equal to or less than 90 nm. STI entails the creation of a trench between adjacent transistors which is then filled with a dielectric material. The dielectric material (for example, silicon dioxide) provides a barrier which impedes the flow of leakage current between the transistors on opposite sides of the trench.

Unfortunately, the introduction of STI trenches can cause unintended stress on the channels of adjacent transistors. Such STI stress is difficult to model and complicates circuit design. For example, STI stress can depend on the channel type, doping level, width, and length of adjacent transistors, as well as the spacing between the channel and the trench and the spacing between additional trenches.

This stress is generally most pronounced in low voltage transistors (e.g., transistors having an operating voltage in the range of approximately 1.2 volts to 3.3 volts). In such low voltage transistors, STI stress can cause reduced electron mobility and increased hole mobility, resulting in slightly enhanced PMOS performance and significantly degraded NMOS performance. The net effect of such changes is slower performance of integrated circuits (for example, CMOS circuits).

For low voltage transistors, such stress effects can be reduced by lining the STI trench with silicon nitride. Unfortunately, such configurations are generally only suitable for low voltage applications. The introduction of the silicon nitride liner can reduce the performance of high voltage transistors, such as flash memory cells and circuitry that supports flash operation or transistors used at input/output pins, and/or having an operating voltage in the range of approximately 5 volts and higher.

For example, the introduction of a silicon nitride liner can interfere with data retention of adjacent flash memory cells. Because silicon nitride tends to absorb hydrogen, it can interfere with the injection and retention of hot electrons with respect to the floating gates of flash memory cells. The silicon nitride layer can also interfere with the growth of additional silicon dioxide in the corners of STI trenches which may be desired to further round the corners in order to provide more uniform electric field distribution.

As a result, conventional STI techniques are generally unsatisfactory for applications where low voltage and high voltage transistors are embedded within a single integrated circuit. Integrated circuits used in programmable logic devices (PLDs) may include high voltage flash memory cells embedded with low voltage transistors in a single integrated circuit. Accordingly, the use of STI trenches in such devices without a silicon nitride liner can increase stress effects on low voltage transistors, but the use of an additional silicon nitride liner can reduce performance of high voltage transistors. Moreover, the creation of a separate high voltage trench after the creation of a low voltage trench on the same substrate can unduly increase manufacturing and design costs.

As a result, there is a need for an improved STI implementation that reduces the disadvantages described above when applied to integrated circuits that include both high voltage and low voltage transistors.

### SUMMARY

In accordance with one embodiment of the present invention, an integrated circuit includes a substrate; a first trench in the substrate; a second trench in the substrate; a first transistor region in the substrate adjacent to and between the first and second trenches; a silicon dioxide liner substantially lining the first and second trenches; a silicon nitride liner on the silicon dioxide liner in the first trench but not on the silicon dioxide liner in the second trench; and a dielectric material filling the first and second trenches.

In accordance with another embodiment of the present invention, an integrated circuit includes a substrate; a trench in the substrate; a silicon dioxide liner substantially lining the trench, the liner having a first portion and a second portion; a silicon nitride liner on the first portion of the silicon dioxide liner but not on the second portion; a dielectric material filling the trench; a first transistor region in the substrate and adjacent to a first side of the trench; and a second transistor region in the substrate and adjacent to a second side of the trench, wherein the trench is adapted to isolate the first transistor region from the second transistor region.

In accordance with another embodiment of the present invention, a method of manufacturing an integrated circuit includes etching first and second trenches adjacent to a transistor region of a substrate; oxidizing a silicon dioxide layer substantially lining the first and second trenches; depositing a silicon nitride layer on the silicon dioxide layer in the first and second trenches; etching the silicon nitride layer from the first trench but not the second trench; and filling the first and second trenches with a dielectric material.

The scope of the invention is defined by the claims, which are incorporated into this section by reference. A more complete understanding of embodiments of the present invention will be afforded to those skilled in the art, as well as a realization of additional advantages thereof, by a consideration of the following detailed description of one or more embodiments. Reference will be made to the appended sheets of drawings that will first be described briefly.

### BRIEF DESCRIPTION OF THE DRAWINGS

FIG. 1 illustrates a process of manufacturing a semiconductor device providing shallow trench isolation (STI) in accordance with the present invention.

FIGS. 2A-E illustrate cross-sectional side views of a first semiconductor device undergoing the process of FIG. 1 in accordance with an embodiment of the present invention.

FIGS. 3A-F illustrate cross-sectional side views of a second semiconductor device undergoing the process of FIG. 1 in accordance with an embodiment of the present invention.

Embodiments of the present invention and their advantages are best understood by referring to the detailed description that follows. It should be appreciated that like reference numerals are used to identify like elements illustrated in one or more of the figures.

### DETAILED DESCRIPTION

The various techniques disclosed herein are applicable to a wide variety of integrated circuits and applications. Several exemplary implementations will be utilized to illustrate the techniques in accordance with one or more embodiments of the present invention. However, it should be understood that this is not limiting and that the techniques disclosed herein may be implemented as desired, in accordance with one or more embodiments of the present invention, in various types of integrated circuits.

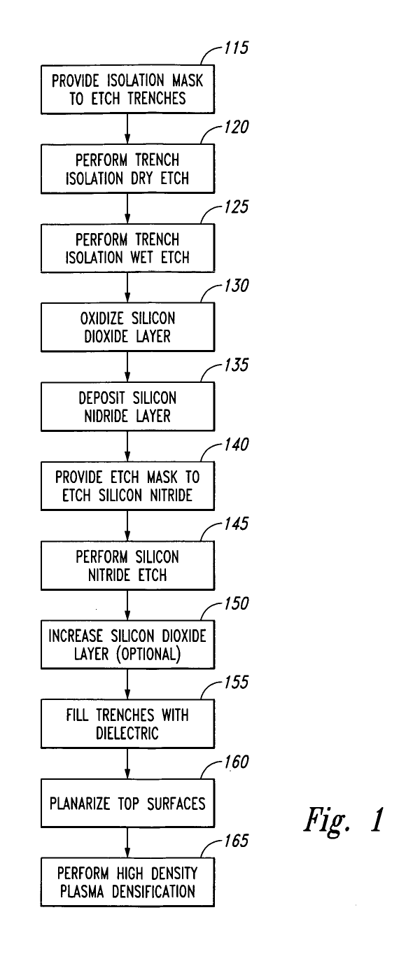

FIG. 1 illustrates a process of manufacturing a semiconductor device providing shallow trench isolation (STI) in accordance with the present invention. As further described herein, the process of FIG. 1 can be performed to create STI regions suitable for use in integrated circuits including both low voltage transistors (e.g., having an operating voltage in the range of approximately 1.2 volts to 3.3 volts) and high voltage transistors (e.g., flash memory cells, transistors used at input/output pins, and/or having an operating voltage in the range of approximately 5 volts and higher). In one embodiment, the process of FIG. 1 can be applied to the manufacture of integrated circuits having a nominal feature size approximately equal to 90 nm or less.

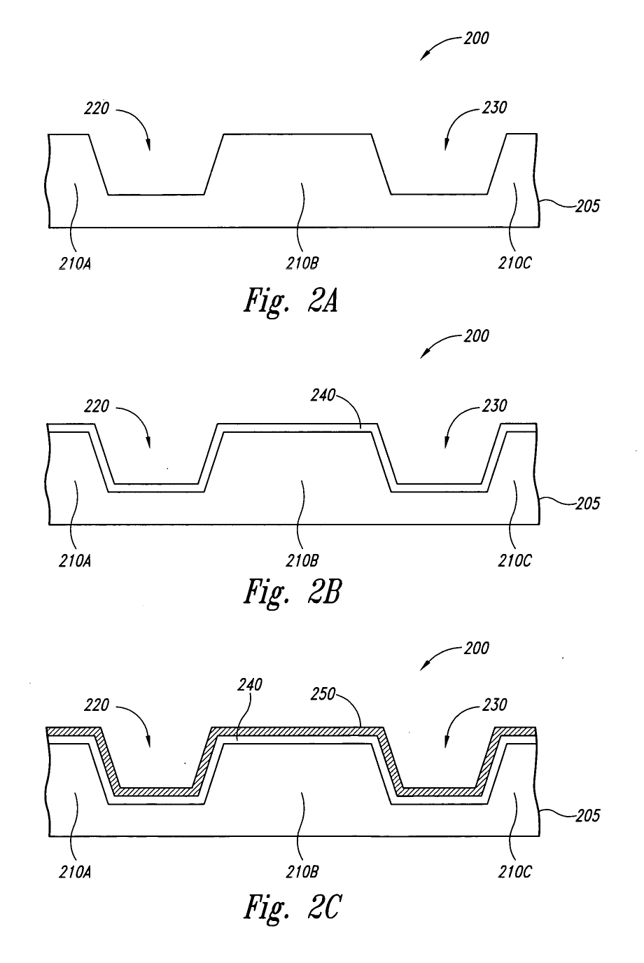

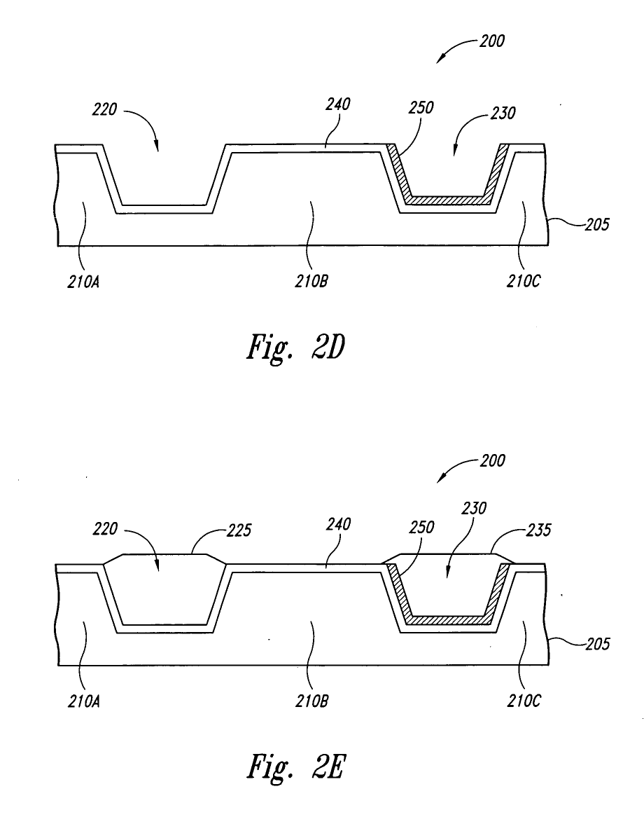

FIGS. 2A-E and 3A-F illustrate cross-sectional side views of first and second semiconductor devices 200 and 300, respectively, undergoing the process of FIG. 1 in accordance with various embodiments of the present invention. Semiconductor devices 200 and 300 may be implemented in any desired type of integrated circuit including both high voltage and low voltage transistors. For example, in one embodiment, each of semiconductor devices 200 and 300 may be a programmable logic device (PLD) such as a complex programmable logic device (CPLD) or a field programmable gate array (FPGA).

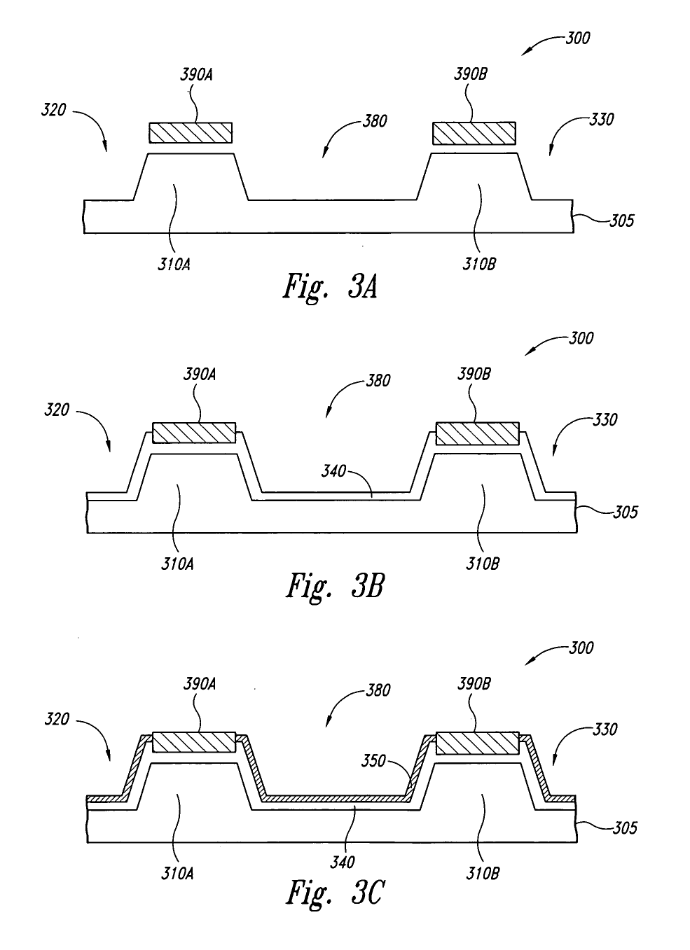

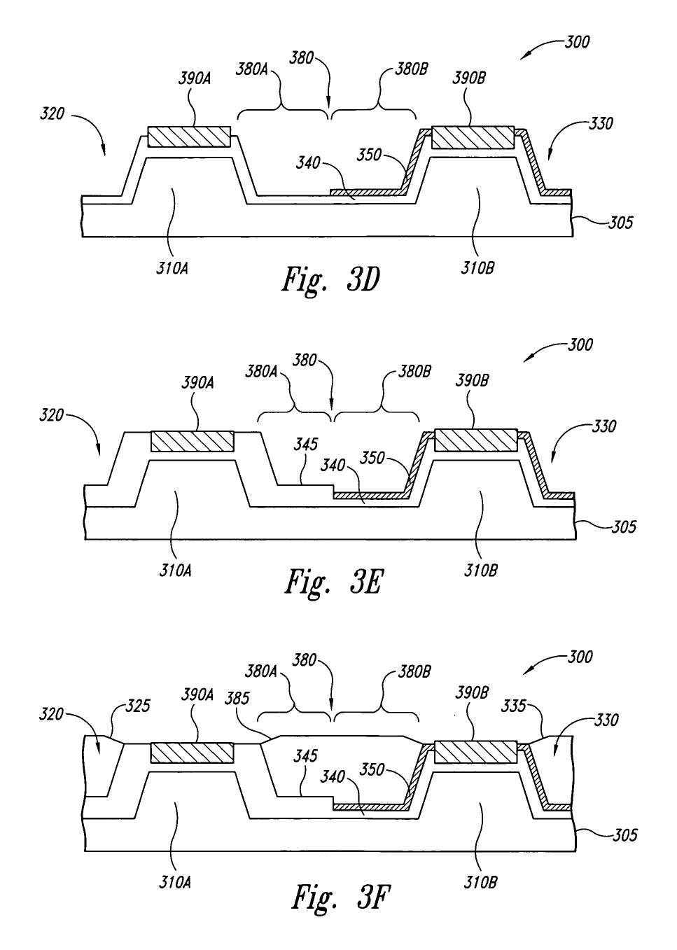

FIGS. 2A and 3A illustrate semiconductor devices 200 and 300 having undergone steps 115 through 125 of the process of FIG. 1 as further described herein. As illustrated, semiconductor devices 200 and 300 include substrates 205 and 305 (for example, p-type substrates) having a plurality of trenches 220/230 and 320/330/380 separating a plurality of transistor regions 210A-B and 310A-B, respectively. It will be appreciated that transistors may be manufactured in transistor regions 210A-B and 310A-B following the process of FIG. 1.

Turning now to the particular steps of FIG. 1, in step 115, an isolation mask is provided to isolate transistor regions 210A-C and 310A-B of substrates 205 and 305, respectively. In one embodiment, the isolation mask provided in step 115 may be in the form of a hard mask deposited on substrate 205 or 305.

A dry etch (step 120) and wet etch (step 125) may then be performed on substrates 205 and 305 to create trenches 220/230 and 320/330/380, respectively. Wet etch step 125 can improve the cleaning and rounding of inside corners of trenches 220/230 and 320/330/380 prior to the performance of further steps in the process of FIG. 1.

It will be appreciated that all portions of any hard mask introduced in step 115 has been removed from semiconductor device 200 in FIG. 2A. In contrast, FIG. 3A illustrates a hard mask 390 (having portions 390A and 390B introduced in step 115) which is allowed to remain in place on semiconductor device 300.

At step 130, exposed surfaces (i.e., unmasked portions) of substrates 205 and 305 are oxidized to form silicon dioxide layers 240 and 340 as illustrated in FIGS. 2B and 3B. In FIG. 2B, silicon dioxide layer 240 provides a silicon dioxide liner in each of trenches 220 and 230, and further covers an entire top surface of substrate 205. In FIG. 3B, silicon dioxide layer 340 covers top surfaces of trenches 320, 330, and 380 but does not appear on top surfaces of transistor regions 310A-B due to the remaining hard mask portions 390A-B. Silicon dioxide layer 340 effectively provides a silicon dioxide liner in each of trenches 320, 330, and 380. In one embodiment, silicon dioxide layers 240 and 340 may be approximately 3 nm thick.

Silicon nitride layers 250 and 350 are then deposited on top of silicon dioxide layers 240 and 340, respectively as illustrated in FIGS. 2C and 3C (step 135). In FIG. 3C, it will be appreciated that remaining mask portions 390A-B prevent the depositing of silicon nitride layer 350 above transistor regions 310A-B. In one embodiment, silicon nitride layers 250 and 350 may be approximately 10 nm thick.

At step 140, an etch mask is provided followed by step 145 which etches portions of silicon nitride layers 250 and 350. FIGS. 2D and 3D illustrate semiconductor devices 200 and 300, respectively, following etching step 145. In the embodiment of FIG. 2D, all portions of silicon nitride layer 250 have been etched away, with the exception of a portion remaining inside trench 230. As a result, the remaining portion of silicon nitride layer 250 effectively provides trench 230 with a silicon nitride liner.

In the embodiment of FIG. 3D, silicon nitride layer 350 has been selectively etched away during step 145. As illustrated, silicon nitride layer 350 has been removed from trench 320 and portion 380A of trench 380. In contrast, portions of silicon nitride layer 350 remain in trench 330 and portion 380B of trench 380. Trench portions 380A and 380B are shown as substantially equal in width. It will be appreciated that the relative widths of the portions can vary to some degree without affecting the efficacy of the structure. As a result, the remaining portion of silicon nitride layer 350 effectively provides trench 330 with a silicon nitride liner, and provides trench 380 with a silicon nitride liner in portion 380B of trench 380.

In optional step 150, additional silicon dioxide is oxidized on exposed portions of the silicon dioxide layer previously oxidized in step 130. FIG. 2D illustrates an embodiment of semiconductor device 200 where optional step 150 is not performed. As a result, the thickness of silicon dioxide layer 240 remains unchanged.

FIG. 3E illustrates an embodiment of semiconductor device 300 where optional step 150 is performed. As a result of optional step 150, the thickness of silicon dioxide layer 340 has increased to create a thicker silicon dioxide layer 345 (i.e., a thicker silicon dioxide liner) in trench 320 and in portion 380A of trench 380. It will be appreciated that the presence of silicon nitride layer 350 prevents the growth of thicker silicon dioxide layer 345 in trench 330 and portion 380B of trench 380.

The introduction of thicker silicon dioxide layer 345 can facilitate improved corner rounding in the corners of trench 320 and portion 380A of trench 380, and improved charge-to-breakdown (QBD) in high voltage transistors manufactured in transistor region 310A. In particular, the presence of thicker silicon dioxide layer 345 in the corners of trench 320 and portion 380B of trench 380 can advantageously cause the corners to be rounded to prevent gate oxide thinning and more evenly distribute electric fields (e.g., less current will be concentrated in trench corners) for high voltage transistors manufactured in transistor region 310A. It will be appreciated that because thicker silicon dioxide layer 345 can reduce the effective width of transistors in transistor region 310A, high voltage transistors are preferred over low voltage transistors in transistor region 310A. In one embodiment, thicker silicon dioxide layer 345 has a thickness in the range of approximately 10 nm to approximately 20 nm.

At step 155, trenches 220/230 and 320/330/380 are filled with dielectric material 225/235 and 325/335/385 (for example, silicon dioxide), respectively. FIGS. 2E and 3F illustrate semiconductor devices 200 and 300, respectively, following step 155. As illustrated in FIG. 2E, transistor regions 210A and 210B are isolated from each other by trench 220 having dielectric material 225 and a silicon dioxide liner in trench 220 provided by silicon dioxide layer 240. In addition, transistor regions 210B and 210C are isolated from each other by trench 230 having dielectric material 235, a silicon dioxide liner in trench 230 provided by silicon dioxide layer 240, and a silicon nitride liner in trench 230 provided by silicon nitride layer 250 (i.e., a dual liner configuration).

As illustrated in FIG. 3F, transistor regions 310A and 310B are isolated from each other by trench 380 having dielectric material 385, a silicon dioxide liner in portion 380A of the trench provided by thicker silicon dioxide layer 345, and liners in portion 380B of the trench provided by silicon dioxide layer 340 and silicon dioxide layer 350 (i.e., a dual liner configuration).

Following step 155, any excess portions of dielectric material 225/235 and 325/335/385 can be removed through planarization (i.e., polishing) of the top surfaces of semiconductor devices 200 and 300, respectively (step 160). A high density plasma densification can then be performed (step 165) to prepare semiconductor devices 200 and 300 for further processing, such as the manufacture transistors in transistor regions 210A-C and 310A-B.

In view of FIGS. 2E and 3F, it will be appreciated that the structure of semiconductor devices 200 and 300 can provide isolation for both low and high voltage transistors embedded within the same device. For example, in semiconductor device 200, high voltage transistors may be provided in transistor regions 210A-B and remain isolated from each other by trench 220. It will be appreciated that because the previously-deposited silicon nitride layer 250 has been removed from trench 220, high voltage transistors manufactured in transistor regions 210A-B need not experience degraded performance (for example, reduced data retention tendencies in flash memory cells) resulting from silicon nitride in close proximity. In addition, the charge-to-breakdown (QBD) of high voltage transistors manufactured in transistor regions 210A-B can also be improved for the same reasons. As a result, the performance of hot carrier injection can be improved in flash memory cells manufactured in such regions.

Also in semiconductor device 200, low voltage transistors may be provided in transistor regions 210B-C and remain isolated from each other by trench 230. Because trench 230 includes silicon nitride layer 250, STI stress effects on low voltage transistors manufactured in transistor regions 210B-C can be reduced.

In semiconductor device 300, high voltage transistors may be provided in transistor region 310A, and low voltage transistors may be provided in transistor region 310B. In this regard, low voltage and high voltage transistors can remain isolated from each other by a single trench 380. Because the previously-deposited silicon nitride layer 350 has been removed from portion 380A of trench 380, high voltage transistors manufactured in transistor region 310A need not experience degraded performance resulting from close proximity of silicon nitride. High voltage transistors in transistor region 310A can also exhibit improved QBD as previously discussed in relation to semiconductor device 200 which can be further improved by the presence of thicker silicon dioxide layer 345.

Because portion 380B of trench 380 includes silicon nitride layer 350, STI stress effects on low voltage transistors manufactured in transistor region 310B can be reduced. It will be appreciated that trenches 320 and 330 can further isolate transistors provided in transistor regions 310A and 310B, respectively.

In view of the present disclosure, it will be appreciated that the various trenches of each of semiconductor devices 200 and 300 can advantageously be manufactured simultaneously in accordance with the process of FIG. 1. As a result, STI features can be provided for low voltage and high voltage transistors on the same substrate without incurring excessive additional processing costs and time.

Embodiments described herein illustrate but do not limit the invention. It should also be understood that numerous modifications and variations are possible in accordance with the principles of the present invention. Accordingly, the scope of the invention is defined only by the claims.

We claim:

1. An integrated circuit comprising:
a substrate;
a first trench in the substrate;
a second trench in the substrate;
a first transistor region in the substrate adjacent to and between the first and second trenches;
a silicon dioxide liner substantially lining the first and second trenches;
a silicon nitride liner on the silicon dioxide liner in the first trench but not on the silicon dioxide liner in the second trench; and
a dielectric material filling the first and second trenches.

2. The integrated circuit of claim 1, wherein the silicon nitride layer is on substantially the entire silicon dioxide liner in the first trench.

3. The integrated circuit of claim 1, wherein the silicon nitride layer is on substantially only half the silicon dioxide liner in the first trench.

4. The integrated circuit of claim 1, wherein the substrate further comprises a second transistor region adjacent to the first trench, wherein the transistor region is adapted to receive a low voltage transistor.

5. The integrated circuit of claim 1, wherein the substrate further comprises a third transistor region adjacent to the second trench, wherein the transistor region is adapted to receive a high voltage transistor.

6. The integrated circuit of claim 1, wherein the substrate comprises a third transistor region adjacent to the second trench, wherein the transistor region is adapted to receive a flash memory cell.

7. The integrated circuit of claim 1, wherein the integrated circuit is a programmable logic device (PLD).

8. An integrated circuit comprising:
a substrate;
a trench in the substrate;
a silicon dioxide liner substantially lining the trench, the liner having a first portion and a second portion;
a silicon nitride liner on the first portion of the silicon dioxide liner but not on the second portion;
a dielectric material filling the trench;
a first transistor region in the substrate and adjacent to a first side of the trench; and
a second transistor region in the substrate and adjacent to a second side of the trench, wherein the trench is adapted to isolate the first transistor region from the second transistor region.

9. The integrated circuit of claim 8, wherein the first portion of the silicon dioxide liner is thinner than the second portion of the silicon dioxide liner.

10. The integrated circuit of claim 8, wherein the first and second portions are substantially equal in width.

11. The integrated circuit of claim 8, wherein the dielectric material is silicon dioxide.

12. The integrated circuit of claim 8, wherein the first transistor region is adapted to receive a low voltage transistor.

13. The integrated circuit of claim 8, wherein the second transistor region is adapted to receive a high voltage transistor.

14. The integrated circuit of claim 8, wherein the second transistor region is adapted to receive a flash memory cell.

15. The integrated circuit of claim 8, wherein the integrated circuit is a programmable logic device (PLD).

16. A method of manufacturing an integrated circuit, the method comprising:
etching first and second trenches adjacent to a transistor region of a substrate;
oxidizing a silicon dioxide layer substantially lining the first and second trenches;
depositing a silicon nitride layer on the silicon dioxide layer in the first and second trenches;
etching the silicon nitride layer from the first trench but not the second trench; and
filling the first and second trenches with a dielectric material.

17. The method of claim 16, further comprising increasing a thickness of the silicon dioxide layer in the first trench prior to the filling.

18. The method of claim 16, further comprising providing a low voltage transistor in the transistor region.

19. The method of claim 16, further comprising providing a high voltage transistor in the transistor region.

20. The method of claim 16, wherein the integrated circuit is a programmable logic device (PLD).
